(19) United States
(12) Patent Application Publication
(10) Pub. No.: US 2016/0123045 A1
(43) Pub. Date: May 5, 2016

(54) DECOUPLED HANDLE SWITCH

(71) Applicant: ADAC Plastics, Inc., Grand Rapids, MI (US)

(72) Inventors: Robert L. Bingle, Grand Rapids, MI (US); Charles Bruce Banter, Northville, MI (US); Gerard Joseph Cummins, Portland, MI (US)

(21) Appl. No.: 14/926,303

(22) Filed: Oct. 29, 2015

Related U.S. Application Data
(60) Provisional application No. 62/069,930, filed on Oct. 29, 2014.

(51) Int. Cl. E05B 81/76; E05B 81/04; H01L 41/113; E05B 81/66; E05B 81/56; E05B 85/10; E05C 19/00

(52) U.S. Cl. CPC E05B 81/76; E05B 85/10; E05B 81/04; E05C 19/00; E05B 81/66; E05B 81/56; H01L 41/1132

(57) ABSTRACT

A handle assembly for actuating a latch of a vehicle door of a vehicle includes a grip assembly with a grip disposed between opposing mounts. The mounts are disposed adjacent a door panel of a vehicle door and space the grip from the door panel. A mounting member is disposed upon an opposite side of the door panel from the grip assembly to secure the grip assembly to the door panel. An indicator is separate from the grip assembly and is disposed at an opposite side of the door panel from the grip assembly. The indicator identifies an intent to actuate the door of the vehicle from an operator clasping the grip assembly. The indicator signals the latch to disengage the vehicle door from the vehicle upon identifying an intent to actuate the door.

### PRIOR APPLICATIONS

The present application claims priority to U.S. provisional patent application No. 62/069,930 filed on Oct. 29, 2014.

### TECHNICAL FIELD

The present application relates generally toward a door handle for a vehicle door. More specifically, the present application relates toward a simplified door handle of a vehicle door that does not require mechanically driven actuation.

### BACKGROUND

Door handles have been used to actuate latch assemblies to open and close or otherwise actuate doors of automotive vehicles for many years. These handles and latches have always been mechanically driven for actuation of a door handle to transfer mechanical motion to a latch assembly. However, recent trends toward electrically actuated door mechanisms are drastically changing the manner in which vehicle doors are open and closed. In some instances, complicated electromechanical door handles that include electronic sensors and mechanical devices to both signal and mechanically actuate a latch assembly are used. The complexity of these devices have made it cost prohibitive for wide spread use across a wide variety of vehicles, particularly low cost vehicles that cannot support the high cost of a complex electromechanical handle.

Complex electromechanical assemblies typically include a sensor or other electronic device be wired into a door handle and subsequently hard wired to an actuator or controller that drives the actuator. The cost associated with providing mechanical and electronic elements has caused electronic door handles to be excluded from most low cost compact vehicles. In addition, failure rates of complex electromechanical door handles have been high relative to old style mechanical handles due the complex designs. Therefore, it would be desirable to provide a new simplified configuration of a grip that reduces mechanical and electronic complexity of a typical electromechanical actuation device of a door handle.

### SUMMARY

A handle assembly for actuating a latch of vehicle door includes a grip assembly and opposing mounts positioned adjacent a door panel. The mounts space the grip from the door panel. A mounting member is disposed upon an opposite side of the grip handle from the grip assembly for supporting the grip assembly upon the door panel. An indicator that is separate from the grip assembly is disposed at an opposite side of the door panel from the grip assembly. The indicator identifies intent to actuate the door of the vehicle from an operator clasping the grip assembly. The indicator signals the latch to disengage the vehicle door from the vehicle.

The handle assembly of the present application provides a substantially simplified handle assembly capable of being used to introduce electronics into low cost vehicles eliminating the associated complexity of a typical electronic door handle and actuator. Separating the indicator from the handle, and locating the indicator inside a vehicle door away from the grip assembly removes the electrical complexity of a typical electronic door handle enhancing the possibility of providing electronic handles to a wider variety of vehicles.

### BRIEF DESCRIPTION OF THE DRAWINGS

Other advantages are the present invention will be readily appreciated, as the same becomes better understood by reference to the following detailed description when considered in connection the accompanying drawings, wherein:

FIG. 1 shows an environmental view of the door handle assembly of the present invention;

FIG. 2 shows a perspective view of the door handle;

FIG. 3 shows a first embodiment of the door handle assembly as viewed along lines 3-3 of FIG. 2; and

FIG. 4 shows an alternative embodiment of the door handle assembly again as viewed along lines 3-3 of FIG. 2.

### DETAILED DESCRIPTION

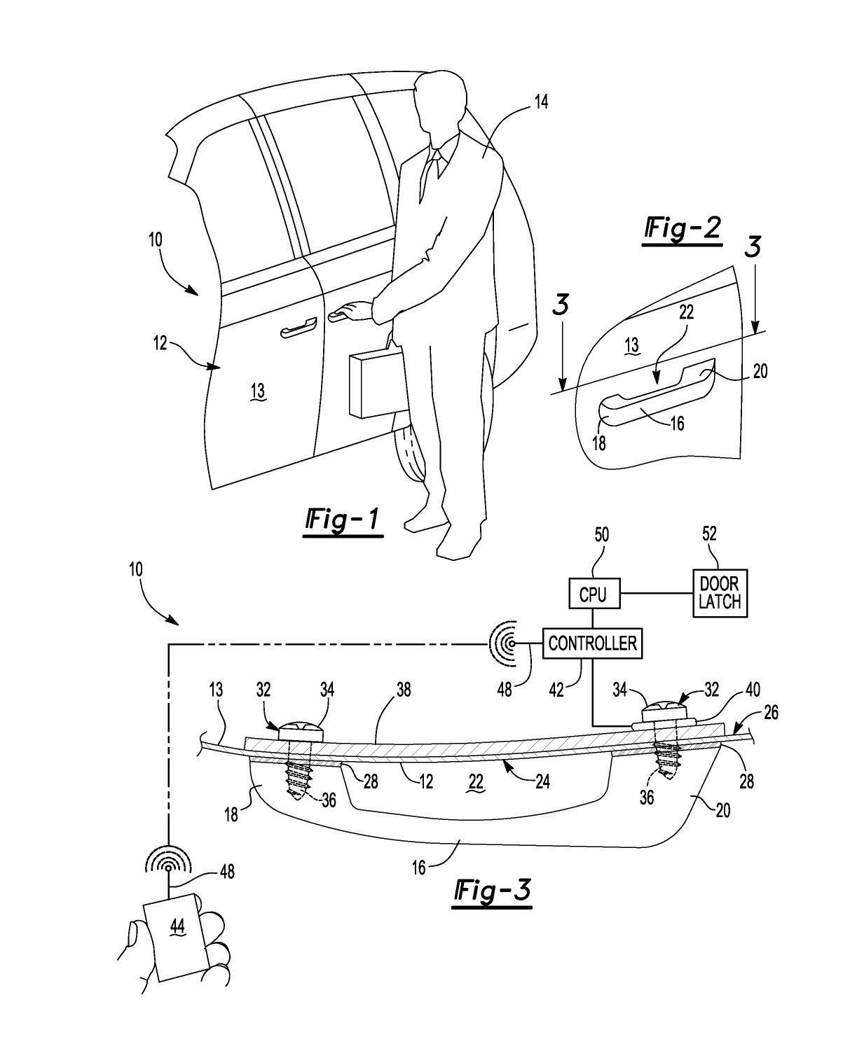

Referring to FIG. 1, a door handle assembly of the present invention is generally shown at 10 being disposed upon a vehicle door 12. As is known to those of ordinary skill in the art, the handle assembly 10 is used to open and close the vehicle door 12. To do so, the handle assembly 10 is clasped by an operator 14 to open and close the vehicle door 12.

As shown in FIG. 2, the handle assembly 10 includes a grip 16 disposed between opposing mounts 18, 20. In this embodiment, the first of the opposing mounts is a forward mount 18 and the second of the opposing mounts is a rearward mount 20. The mounts 18, 20 a grip 16 from a door panel 13 of the door 12 allowing access for the digits of an operator 14 of actuating the vehicle door 12. In this embodiment, the handle assembly 10 includes an aerodynamic shape having the forward mount 18 protruding less from the door panel 13 than does the rearward mount 20 providing the least amount of turbulent airflow caused by the handle assembly 10 when the vehicle is in transit.

Referring now to FIG. 3, the door panel 13 includes an exterior surface 24 and interior surface 26. A gasket 28 (or spacer) is disposed between the forward mount 18 and the exterior surface 24 of the door panel 13. In a similar manner, a second gasket 30 is disposed between the rearward mount 20 and the exterior surface 24 of the door panel 13. The gaskets 28, 30 prevent the mounts 18, 20 from scratching or otherwise damaging the exterior surface 24 of the door panel 13. It is also contemplated that the gaskets 18, 20 may be electrically conductive as will be explained further herein below. The handle assembly 16, in this embodiment, is a solid handle formed from a rigid polymeric material, a glass filled polymeric material, a carbon filled polymeric material, or a fiber filled polymeric material providing a sufficient rigidity and durability necessary of an exterior door handle 10. Alternatively, the handle assembly 16 is hollow being formed either by blow molding or assembling various handle elements. Furthermore, the handle includes a coating (not shown) providing an aesthetically pleasing appearance matching the appearance of the door 12. Alternatively, the handle 16 is molded in color providing a distinguishing appearance to that of the door 12.

A securing element 32 is used to fixedly attach the forward mount 18 to the door 12 Likewise, a securing element 32 is used to fixedly attach the rearward mount 20 to the door 12. The securing element 32 is represented as a screw having a screw head 34. The screw head 34 is disposed at the interior surface 26 of the door panel 13 on an opposite side of the door panel 13 from the grip 16. A threaded shaft 36 passes through the door panel 13 and is received by each of the forward mount 18 and the rearward mount 20 for securing the handle 16 to the door panel 13. Alternatively, the securing element 32 includes a bolt and nut arrangement is contemplated where the nut (not shown) is integrally molded or otherwise engaged with the grip 16 and receives threaded engagement with the threaded shaft 36.

A mounting member 38 is disposed upon the interior surface 26 of the door panel 13. The mounting member 38 is retained by the screw head 34 against the interior surface 26 of the door panel 13 to provide structural support to the door panel 13. In this manner, a mounting member 38 reduces an amount of flexure of the door panel 13 when the grip 16 is clasped by the operator 14, the purpose of which will also become more evident herein below.

As best represented in FIG. 3, an indicator 40 is retained against the mounting member 38 by the screw head 34 of the securing element 32. The indicator 40 detects intent to change the disposition of the door 12 by an operator and signals a controller 42 of such intent. Therefore, the indicator 40 is interactive with the controller 42, which is encoded to receive and translate signals from the indicator 40. The controller 42 receives a proximity signal from a key FOB 44. It should be understood by those of ordinary skill in the art that a FOB antenna 46 transmits and receives a signal with the controller antenna 48. Proximity of the key FOB 44 to the controller 42 indicates a possibility that the door 12 will be opened or closed. The one embodiment, the indicator 40 is not activated unless the key FOB 44 is proximate the controller 42 rendering the indicator 40 incapable of signaling the controller 42 to unlatch the door 12.

The controller 42 is also encoded to communicate with the vehicle operating system or central processing unit (CPU) 50. When the controller 42 is signaled by the indicator 40 of a change in disposition, the controller 42 signals the CPU 50 to deliver an electronic pulse to a door latch 52 to actuate the door latch 52.

The indicator 40 is a separate element from the handle 16. The indicator 40 is contemplated to be a mechanical switch, a piezoelectric device, an infrared sensing device, or any sensor or device capable of detecting a change in disposition of the handle 16.

In one embodiment, the indicator 40 indicates a change in disposition of the door 12 when the operator 14 pulls or exerts pressure upon the handle 16. The indicator 40 indicates flexure or pressure changes upon the door panel 13 when the operator pulls upon the grip 16. In the case of a piezoelectric device, a piezoelectric material is sandwiched between the screw head 34 and the mounting member 38. During installation, the piezoelectric material is calibrated based upon the amount of torque received by the securing element 32 and caused by the screw head 34. It should be understood by those of ordinary skill in the art that piezoelectric material generates a voltage output in response to force placed upon the piezoelectric material. As such, clasping and pulling a door handle will apply force to the piezoelectric material comprising the indicator 40 resulting in an electronic pulse signaled to the controller 42 indicating an intent of an operator 14 to open the door 12. Additionally, the piezoelectric material is adapted to measure acceleration of the material to avoid unintended opening of the vehicle door 12 during a typical jounce and rebound action experienced by a vehicle driven over uneven roadways.

In a further embodiment, a simple mechanical switch that is capable of measuring minor flexure of the mounting member 38 by pulling on the grip 16. As such, flexing the mounting member 38 causes the mechanical device to contact closing the electrical circuit with the controller 42 thereby signaling the controller 42 to cause the door latch 52 to be actuated.

The still further embodiment, the indicator 40 is formed of an infrared sensing device. When an infrared sensing device is selected, the indicator 40 includes an infrared light source that projects infrared light onto the mounting member 38 or the interior surface 26 of the door panel 13. A light sensor detects slight movements of the door panel 13 or the mounting member 38 by measuring movement of the infrared light in response to the operator 14 clasping the handle 16. The infrared light is either reflected off the interior surface 26 of the door panel 13 or the mounting member 38 to a light sensor. Alternatively, the light sensor is affixed to the interior surface 26 or of the door panel 13 or the mounting member 38 and the infrared light is directed the light sensor from the source of infrared light. In either embodiment, the source of infrared light and the light sensor are contained within the indicator 40 at the interior surface 26 of the door panel 13 eliminating the need to provide wiring to the handle 16. Therefore, the indicator 40 of this embodiment operates in the same manner as the prior embodiments. The indicator 40, signals the controller 42 when a change in tension or pressure between the door panel 13, the securing element 32, or mounting member 38 is detected to cause the door latch 50 to be actuated by way of the CPU 50 as set forth above.

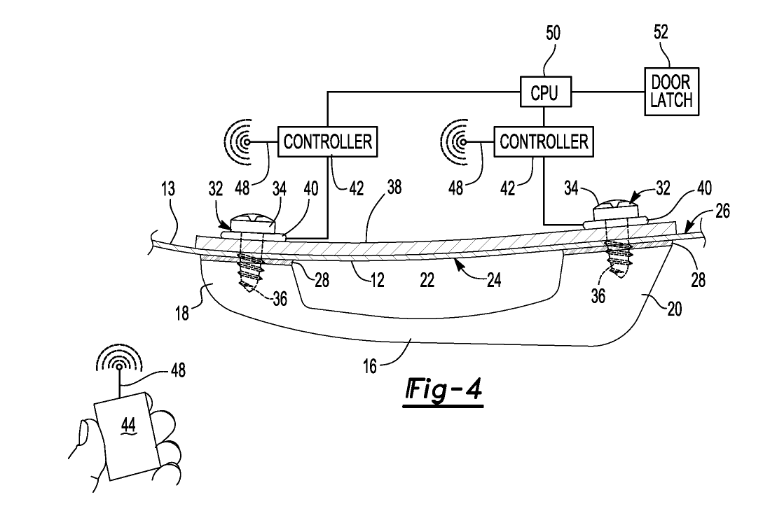

FIG. 4 shows an alternative embodiment where two indicators 40 are included. In this embodiment, an indicator 40 is located at each of the securing elements 32 to ensure a proper signal is sent to the controller 42 associated with each of the indicators 40. Including two indicators 40 provides a signal redundancy that serves as a backup in the event one of the indicators 40 fails. A similar controller 40 or parallel controllers are within the scope of the present invention. In a similar manner as the previous embodiment, the controller 42 or controllers 42 signal the CPU 50 to actuate the door latch 52.

The invention has been described in an illustrative manner, and it is to be understood that the terminology that has been used is intended to be in the nature of words of description rather than of limitation. Obviously, many modifications and variations of the present invention are possible in light of the above teachings. It is therefore to be understood that within this specification the referenced numerals are merely for convenience, and are not to be in any way limiting, so that the invention may be practiced otherwise therein specifically described.

What is claimed is:

1. A handle assembly for actuating a latch of a vehicle door of a vehicle, comprising:
a grip assembly including a grip disposed between opposing mounts being at a door panel, with said mounts spacing said grip from the door panel;
a mounting member disposed upon an opposite side of the door panel from said grip assembly for securing said grip assembly to said door panel;
an indicator separate from said grip assembly and disposed at an opposite side of the door panel from said grip assembly, said indicator identifying an intent to actuate the door of the vehicle from an operator clasping said grip assembly; and
said indicator signaling the latch to disengage the vehicle door from the vehicle.

2. The assembly set forth in claim 1, wherein said mounting member is disposed proximate each of said opposing mounts.

3. The assembly set forth in claim 1, wherein said mounting member extends between said opposing mounts.

4. The assembly set forth in claim 1, further including a securing element for securing said grip assembly, said mounting member and said indicator to the door panel.

5. The assembly set forth in claim 4, wherein said indicator identifies a change in disposition of any of said securing element, said grip assembly, said mounting member and the door pad and signals the change in disposition to the latch.

6. The assembly set forth in claim 1, wherein said indicator comprises any of a mechanical switch, piezo electric sensor, or infrared sensor for detecting intent to actuate the latch.

7. The assembly set forth in claim 1, wherein said indicator detects any of flexure and pressure.

8. The assembly set forth in claim 1, wherein said grip assembly is immovably affixed to the door panel.

9. The assembly set forth in claim 1, wherein a gasket is disposed between said grip assembly and the door assembly for insulating said grip assembly from the door panel.

10. A handle assembly for actuating a door latch of a vehicle door; comprising:
a handle fixedly attached to a door panel of the vehicle door being disposed a fixed disposition relative to the door panel;
said handle including a grip being interconnected to the door panel; said grip dispensing indication of an intent to open the vehicle door to the door panel upon being clasped by an operator; and
said door panel transferring said indication of intent to open the vehicle door to an indicator and said indicator signaling the door latch to release said door thereby allowing the operator to open said door.

11. The assembly set forth in claim 10, wherein said indication of intent to open the door includes flexure of the door panel.

12. The assembly set forth in claim 10, wherein said indication of intent to open the door includes an electrical charge generated by the operator.

13. The assembly set forth in claim 10, wherein said indication of intent to open the door includes acceleration of the door panel relative to the car.

14. The assembly set forth in claim 10, wherein said indicator comprised one of a mechanical switch, a piezoelectric device; and an infrared device.

15. The assembly set forth in claim 10, wherein a mounting member is disposed between the door panel and said indicator.

16. The assembly set forth in claim 10, wherein indicator includes a controller and the vehicle includes a central processing unit (CPU), said controller being interconnected to said CPU for signaling said CPU an intent to disengage the door latch.

17. The assembly set forth in claim 10, wherein said grip is fixedly attached to the door panel with a securing element.

18. The assembly set forth in claim 10, wherein said indicator is calibrated after said grip has been fixedly attached to the door panel.

19. The assembly set forth in claim 10, wherein said indicator signals said controller the operator's intent to actuate the door latch exclusive of direct contact with said grip.
